(19) United States
(12) Patent Application Publication
(10) Pub. No.: US 2013/0203211 A1
(43) Pub. Date: Aug. 8, 2013

(54) METHOD FOR COATING A SUBSTRATE WITH ALUMINIUM-DOPED ZINC OXIDE

(71) Applicants: Volker Sittinger, Braunschweig (DE); Bernd Szyszka, Braunschweig (DE); Wilma Dewald, Braunschweig (DE); Frank Säuberlich, Dunningen (DE); Bernd Stannowski, Berlin (DE)

(72) Inventors: Volker Sittinger, Braunschweig (DE); Bernd Szyszka, Braunschweig (DE); Wilma Dewald, Braunschweig (DE); Frank Säuberlich, Dunningen (DE); Bernd Stannowski, Berlin (DE)

(21) Appl. No.: 13/519,030

(22) PCT Filed: Dec. 23, 2010
(86) PCT No.: PCT/EP10/70655

§ 371 Date: Oct. 23, 2012

(30) Foreign Application Priority Data
Dec. 23, 2009 (DE) 10 2009 060 547.9

(51) Int. Cl. H01L 21/768; H01L 31/02

(52) U.S. Cl. CPC H01L 21/768; H01L 31/02016
USPC 438/98; 438/609

(57) ABSTRACT

A method coats a substrate with an aluminum-doped zinc oxide. The method includes generating a nucleation coating between 5 nm and 400 nm thick and having zinc oxide or doped zinc oxide, in particular aluminum-doped zinc oxide, on a surface of a substrate by atomizing a solid target. A quasi-epitaxially propagating top coating is generated and contains an aluminum-doped zinc oxide on the nucleation coating and the top coating is wet chemically etched.

The present invention relates to a process for coating a substrate with aluminum-doped zinc oxide.

The prior art discloses that silicon thin-film solar cells configured in what is called a p-i-n “superstrate” configuration require transparent conductive oxide layers (TCO layers for short; TCO=transparent conductive oxide). These TCO layers must have low layer resistances with a high transparency in the visible spectral range (400 to 800 nm) for solar cells made from amorphous silicon (a-Si:H) and up to 1100 nm for solar cells made from microcrystalline silicon (μc-Si:H). In addition, a suitable surface structure and a lateral structure size—more particularly from the point of view of surface roughness—are required to effectively couple light into the solar cell by scattering and thus to achieve a stronger absorption in the silicon layers.

The TCO layers can be produced especially by using what are called atomization processes (also known synonymously as sputtering processes). Atomization involves extraction of atoms from a solid-state target by atomization with high-energy noble gas ions to convert them to the gas phase. The atoms can condense on a substrate provided close to the solid-state target from which the atoms are extracted, such that they form a layer on the surface of the substrate.

For use in silicon thin-film solar cells, layers of aluminum-doped zinc oxide (ZnO:Al layers) are particularly suitable. The ZnO:Al layers produced with the aid of sputtering processes generally have relatively smooth surfaces. This means that the roughness thereof is only a few nanometers. A wet-chemical etching step can roughen these layers, so as to form crater-like structures with a relatively broad spectrum of structural parameters (see: J. Müller, G. Schöpe, O. Kluth, B. Rech, V. Sittinger, B. Szyszka, R. Geyer, P. Lechner, H. Schade, M. Ruske, G. Dittmar, H.-P. Bochem, in: Thin Solid Films 442 (2003), p. 158; J. Müller, B. Rech, J. Springer, M. Vanecek: “TCO and light trapping in silicon thin film solar cells” in: Solar Energy 77 (2004), p. 917-930; J. Müller, G. Schöpe, H. Siekmann, B. Rech, T. Rebmann, W. Appenzeller, B. Sehrbrock: “Verfahren zur Behandlung von Substraten mit vorstrukturierter Zinkoxidschicht”, German Patent DE 10 2004 017 680 B4). The root mean square roughness (hereinafter RMS roughness) can thus be increased to about 200 nm. Such surface-textured layers have very good light scattering properties and can be produced particularly with the aid of high-frequency magnetron sputtering processes (HF magnetron sputtering processes for short) using ceramic ZnO solid-state targets (see B. Rech, O. Kluth, T. Repmann, T. Roschek, J. Springer, J. Müller, F. Finger, H. Stiebig and H. Wagner, in: Sol. Energy Mater. Sol. Cells 74, page 439 (2002); O. Kluth, G. Schöpe, J. Hüpkes, C. Agashe, J. Müller, B. Rech, in Thin Solid Films 442 (2003) page 80-85. M. Breedon et al.: “ZnO Nanostructured Arrays Grown from Aqueous Solutions on Different Substrates” in “Conference Proceedings, International Conference on Nanoscience and Nanotechnology”, ICONN 2008, p. 9 to 12 discloses different substrates with ZnO layers which are produced from aqueous solution and are applied to a ZnO nucleation layer which has a thickness of 1.2 μm and is produced by high-frequency magnetron sputtering. This explicitly concerns the production of what are called “nanorods”. In this document, the ZnO layer is used to promote the orientation and uniformity of nanorods.

In principle, it is advantageous to coat a substrate by high-frequency magnetron sputtering with aluminum-doped zinc oxide in order to obtain suitable layer properties. However, high-frequency magnetron sputtering is a relatively slow atomization process compared to DC magnetron sputtering, and so the production of aluminum-doped zinc oxide layers on a substrate can take a very long time.

It has also been shown that the process conditions during the atomization crucially determine the resulting optical and electrical material properties of the ZnO layers. The surface structures which can be produced by the wet-chemical etching are influenced here particularly by the process parameters of temperature and deposition pressure and by the substrate material selected. A further important parameter is the doping of the solid-state target with aluminum. For instance, it is possible, according to the dopant concentration and temperature, to find an optimal “coating window” for layers which are produced by HF magnetron sputtering processes, said layers having an optimized light guide structure after the wet-chemical etching step (see M. Berginski, B. Rech, J. Hüpkes, H. Stiebig, M. Wuttig: “Design of ZnO:Al films with optimized surface texture for silicon thin-film solar cells” in: SPIE 6197 (2006), p. 61970Y 1-10; M. Berginski, J. Hüpkes, M. Schulte, G. Schöpe, H. Stiebig, B. Rech: “The effect of front ZnO:Al surface texture and optical transparency on efficient light trapping in silicon thin-film solar cells” in: Journal of Applied Physics 101, p. 74903 (2007). The optimal configuration of the interface has a crucial influence on the efficiency of the solar cell. What is important in this context is the optimization of the roughness with regard to the lateral and vertical dimensions. In this context, it has been found to be advantageous when the lateral dimensions are in the order of magnitude of the wavelength of the light to be scattered and hence in the pm range for solar cells made from microcrystalline silicon (μc-Si:H) or what are called tandem cells (a-Si:H/μc-Si:H), and a mean roughness of about 100 nm to about 200 nm is attained.

The texture etching of ZnO:Al layer systems exploits the anisotropy of the etching rate of crystalline ZnO layers in order to convert conventionally smoothly deposited layers with columnar growth (lateral dimension about 50 to 100 nm) to a smooth surface, the lateral dimensions of which under optimized process conditions are within the μm range. In the case of texture etching, it is of particular interest that the generally difficult production of large crystals is avoided. The process is based on the etching of the ZnO:Al layers in dilute acid (for example 0.5% HCl). The etching is effected anisotropically, such that the O-terminated crystals deposited in the c-axis orientation are etched one order of magnitude more rapidly than the corresponding Zn-terminated crystals. In the orthogonal direction, it is even possible to observe an increase in the etching rate by the factor of 40 (cf. F. S. Hickernell: “The microstructural properties of sputtered zinc oxide SAW transducers.” in: Review Phys. Appl. 20 (1985), p. 319-324).

In principle, it is also possible to find an etching morphology comparable to the case of optimized high-frequency atomization conditions with DC magnetron atomization processes on a ceramic solid-state target and by means of reactive moderate-frequency atomization (MF atomization) on a metallic solid-state target (see B. Rech, T. Repmann, J. Hüpkes, M. Berginski, H. Stiebig, W. Beyer, V. Sittinger, F. Ruske: “Recent progress in amorphous and microcrystalline silicon based solar cell technology”, in: Proceedings of 20th European Photovoltaic Solar Energy Conference, (Barcelona) (2005), p. 1481-1486; J. Hüpkes, B. Rech, O. Kluth, T. Repmann, B. Zwaygardt, J. Müller, R. Drese, M. Wuttig: “Surface textured MF-sputtered ZnO films for microcrystalline silicon-based thin-film solar cells” in: Solar Energy Materials and Solar Cells 90 (2006), p. 3054-3060). However, it has been found that this etching morphology is only very rarely reproducible and hence can be implemented on comparatively large areas only with very great difficulty.

In the case of reactive moderate-frequency (MF) magnetron sputtering of ZnO:Al, the desired etching morphology can be established by the process regime (see Szyszka, B.: “Magnetron sputtering of ZnO films”. In: Transparent Conductive Zinc Oxide: Basics and Applications in: Thin Film Solar Cells. Ellmer, K.; Rech, B.; Klein, A. (Eds.). Springer Series in Materials Science, 2007, p. 187-229). It is known that the desired Zn termination of the ZnO crystals can be achieved by an operating regime in metallic mode at high substrate temperature when excess zinc desorbs from the surface due to the high vapor pressure. High substrate temperatures are generally found to be advantageous in this context. At a high partial oxygen pressure, the result is rough, fissured structures with a low lateral dimension. The etch images show deep holes. It is suspected that O-terminated crystals have been etched here with a high etching rate, whereas there is apparently no etch attack via the flanks of the surrounding grain. One possible approach to an explanation for this is the thermodynamically favorable segregation of aluminum at the particle boundaries, which leads there to formation of an etch-resistant Al₂O₃ accumulation. At a low partial oxygen pressure, the result is flat structures, which indicates uniform Zn termination. It is additionally found that repeated passes before a cathode are needed to suppress through-etching at defects.

The growth and hence the termination of the layer are determined by the different energy inputs (more particularly by the substrate temperature, uncharged particle energies, ion energies). Ion current measurements in the production of aluminum-doped zinc oxide show the different ion energy contribution according to plasma excitation. In order to achieve an etching structure suitable for solar cells, it is therefore important to influence the layer growth such that a predominantly Zn-terminated surface with few O-terminated crystals is present.

DE 10 2004 048 378 A1 discloses thin zinc oxide films which consist of a substrate composed of monocrystalline sapphire (Al₂O₃) with a- or c-section orientation and a ZnO layer with epitaxial crystal structure. These thin zinc oxide films enable particularly intense and rapid light emission (luminescence) in the ultraviolet spectral range at room temperature. These thin zinc oxide films are produced in a laser-based manner by laser plasma deposition.

In J. T. Chen et al.: “The effect of Al doping on the morphology and optical property of ZnO nanostructures prepared by hydrothermal process” (Applied Surface Science 255 (2009) p. 3959-3964), nucleation layers composed of ZnO and having a thickness of 200 nm are used on an indium-tin oxide substrate (ITO substrate), these being prepared from aqueous solution by rotational coating.

It is an object of the present invention to provide a process for coating a substrate with aluminum-doped zinc oxide, by means of which ZnO:Al layers with improved layer properties, high process reliability and high deposition rate can be obtained.

This object is achieved by a process having the features of claim 1. The dependent claims relate to advantageous developments of the invention.

A process according to the invention for coating a substrate with aluminum-doped zinc oxide comprises the steps of
producing a nucleation layer which has a thickness between 5 nm and 400 nm and comprises zinc oxide or doped, especially aluminum-doped, zinc oxide on the surface of the substrate by atomizing a solid-state target;
producing an outer layer which grows onto the nucleation layer in a quasi-epitaxial manner and comprises aluminum-doped zinc oxide; and
wet-chemically etching the outer layer.

It has been found that the ZnO:Al layers produced on the substrate by means of the process according to the invention have advantageous light guide structures, such that they are particularly suitable as a front contact for silicon thin-film solar cells. According to the invention, the nucleation layer, which comprises zinc oxide or doped, especially aluminum-doped, zinc oxide, is produced by atomizing a solid-state target. The doped zinc oxide may in principle have any dopants. As well as aluminum, particular mention should be made here of doping with gallium, indium or else boron. This nucleation layer gives optimized conditions for the outer layer, which likewise comprises aluminum-doped zinc oxide, to be able to grow onto the nucleation layer in a quasi-epitaxial manner. The substrate materials used may especially be glass, plastic, metals or ceramics. The wet-chemical etching of the outer layer, which structures it, is preferably effected with dilute hydrochloric acid. The nucleation layer may advantageously have a thickness of <300 nm. The nucleation layer serves primarily to positively influence the electrical properties of the layer which grows on later and comprises ZnO:Al, and the etching characteristics thereof. The nucleation layer can especially also be used on amorphous substrates, for example glass. Since the layer is still a polycrystalline layer and not a monocrystalline layer, the process here too is not epitaxy but merely quasi-epitaxy.

In a particularly advantageous embodiment, it is proposed that the nucleation layer is produced on the substrate with a thickness between 5 nm and 30 nm. It has been found that, surprisingly, even relatively thin nucleation layers (especially nucleation layers of thickness about 5 to about 30 nm) are sufficient to promote the quasi-epitaxial growth of the outer layer onto the nucleation layer.

In order to obtain optimized growth of the outer layer onto the nucleation layer, in a particularly preferred embodiment, it is proposed that the nucleation layer is produced by high-frequency magnetron sputtering of a ceramic solid-state target which comprises ZnO and a content of Al₂O₃ and/or any other dopants, and more particularly retains or at least virtually retains the lattice structure (and thus changes only insignificantly). At the same time, it has been found that such a nucleation layer produced by high-frequency magnetron sputtering can continue its predominant Zn termination in a quasi-epitaxial manner in the course of subsequent deposition of the ZnO:Al layer, which can advantageously be effected, for example, by DC magnetron sputtering or moderate-frequency magnetron sputtering. An outer layer produced in such a way, after the wet-chemical etching step, which can especially be performed with dilute hydrochloric acid, has an improved light guide trap structure. This is notable particularly in that the crater width is predominantly in the region of the incident light wavelength in the near infrared spectral range (about 1 μm). It has also been found that the depth of the craters can be varied to a certain degree through the etching time.

In an advantageous embodiment, it is proposed that the nucleation layer is produced using a ceramic solid-state target comprising ZnO and a content of Al₂O₃ greater than 0% by weight and less than 1% by weight, and is atomized by high-frequency magnetron atomization at a temperature T>300° C. It has been found that, through the adjustment of the content of Al₂O₃ (greater than 0% by weight and less than 1% by weight) at a temperature T>300° C., an optimized “coating window” can be obtained for the atomization of the ceramic solid-state target for production of the nucleation layer.

In an alternative embodiment, it is also possible that the nucleation layer is produced using a ceramic solid-state target which comprises ZnO and a content of Al₂O₃ between 1 and 2% by weight and is atomized by high-frequency magnetron atomization at a temperature T≦300° C. It has been found that, through the adjustment of the content of Al₂O₃ between 1 and 2% by weight at a temperature T≦300° C., a further optimized “coating window” can be obtained for the atomization of the ceramic solid-state target for production of the nucleation layer.

The present process is a dynamic coating process in which the substrate, during the atomization, is moved at a particular speed past the solid-state target from which the atoms are extracted. In order to further improve the growth of the nucleation layer on the substrate and the quality of the nucleation layer, in a particularly advantageous embodiment, the deposition rate with which the nucleation layer is applied to the substrate is less than 20 nm m/min.

In a further alternative embodiment, it is also possible that the nucleation layer is produced using a ceramic solid-state target comprising ZnO and a content of Al₂O₃ and/or any other dopants and is atomized by DC magnetron sputtering, the deposition rate with which the nucleation layer is applied to the substrate being less than 20 nm m/min. It is thus advantageously also possible that the nucleation layer is produced by DC magnetron sputtering of a ceramic solid-state target. In this case, the deposition rate must be adjusted such that it is less than 20 nm m/min, in order that the nucleation layer has appropriate characteristics, such that the outer layer can grow onto the nucleation layer in a quasi-epitaxial manner.

In an advantageous embodiment, it is proposed that the outer layer which grows onto the nucleation layer is produced by atomizing a ceramic solid-state target comprising ZnO and a content of Al₂O₃ by DC magnetron atomization or DC pulsed magnetron atomization. DC magnetron atomization and DC pulsed magnetron atomization of a ceramic solid-state target enable rapid growth of the outer layer on the nucleation layer. In addition, these atomization processes are very robust from a process technology point of view.

In an alternative advantageous embodiment, it is proposed that the outer layer which grows onto the nucleation layer is produced by atomizing a metallic solid-state target comprising aluminum-doped zinc oxide (Zn:Al) in a reactive gas process by DC magnetron atomization or moderate-frequency magnetron atomization. These processes too enable rapid layer growth and are notable for their robustness with correspondingly rapid oxygen partial pressure regulation.

The outer layer which grows onto the nucleation layer can alternatively also be produced by
hollow cathode gas flow atomization; or
vapor deposition; or
wet-chemical deposition; or
atmospheric chemical gas phase deposition (CVD); or
low-pressure CVD (LP-CVD); or
atmospheric plasma-enhanced chemical gas phase deposition (PECVD); or
low-pressure PECVD.

The process described here provides a new approach for producing zinc oxide layers with good etching properties and excellent electrical mobility. The deposition rate of the overall layer can advantageously be greatly enhanced, since the nucleation layer which has grown on slowly determines the growth.

Further features and advantages of the present invention become clear from the description of preferred working examples which follows.

### WORKING EXAMPLE 1

In the first working example, several samples were examined, in which the nucleation layer (or seed layer) produced by high-frequency magnetron atomization (HF magnetron sputtering) has been reduced stepwise from 390 nm to 25 nm.

Deposited on the nucleation layer in each case was an outer layer of ZnO:Al by DC magnetron atomization, and the total thickness was about 1 μm. All layers deposited in this way were etched with 0.5% hydrochloric acid (HCl).

The etching morphology of the samples was subsequently examined by means of scanning electron microscopy (SEM). It was found that all outer layers have similar etching morphologies irrespective of the thickness of the nucleation layer. All SEM images showed a similar etching structure with crater widths of approx. 1 μm. The etching structures are comparable with the outer layers which are produced purely by means of HF magnetron sputtering.

The application of a relatively thin nucleation layer can thus have a lasting influence on the growth of the layer produced subsequently by DC magnetron sputtering. The nucleation layer applied first to the substrate apparently ensures quasi-epitaxial growth of the ZnO:Al layer which grows onto it.

It has also been found that the ZnO:Al layers thus produced have an excellent specific resistivity between 286 and 338 μOhmcm. This is likewise attributable to the quasi-epitaxial growth of the ZnO:Al layer onto the nucleation layer.

### WORKING EXAMPLE 2

Two layers with different thickness of the nucleation layer (seed layer thickness) were taken from the sputtering device and exposed to normal atmosphere. The layers were then introduced into the sputtering device together with an uncoated glass slide for the production of the ZnO:Al outer layer by DC magnetron sputtering. These experiments served as a test for any possible change in etching structure due to vacuum breakage (accumulation of moisture and so forth on the layer). In addition, the different etching structure in the case of pure DC deposition was verified in comparison to the nucleation layers produced by HF magnetron sputtering.

SEM studies showed that the etching morphology of the pure DC layer exhibits much smaller structure sizes of the etching trenches. In comparison, the substrates provided with the nucleation layer produced by high-frequency magnetron sputtering exhibited much more marked etching craters, the layers with the same etching depth having somewhat flatter structures compared to the samples which have not been exposed to atmosphere. These structures can be optimized by an adjustment in the etching time.

### Sample Characterization

By atomic force microscopy, the mean roughnesses (RMS roughnesses) listed in table 1 were determined for several layers which had been produced with the aid of the processes presented here. In this way, the structures shown in the SEM images were also detected quantitatively.

TABLE 1

| | Thickness | | Number of | Number of | | Lateral |
|---|---|---|---|---|---|---|
| | of the | | HF | DC | | structure |
| | nucleation | RMS | sputtering | sputtering | Vacuum | parameter |
| No. | layer [nm] | [nm] | passes | passes | breakage | [μm] |
| 1 | 900 | 162 | 30 | 0 | no | 1.1 |
| 2 | 387 | 126 | 15 | 15 | no | 1.3 |
| 3 | 155 | 168 | 6 | 24 | no | 1.6 |
| 4 | 77 | 143 | 3 | 27 | no | 1.4 |
| 5 | 26 | 151 | 1 | 29 | no | 1.3 |
| 6 | 0 | 55 | 0 | 30 | no | 0.4 |
| 7 | 26 | 96 | 1 | 29 | yes | 1.1 |
| 8 | 155 | 112 | 6 | 24 | yes | 1.1 |

The samples with a nucleation layer without vacuum breakage (samples No. 2 to 5) showed, irrespective of the thickness of the nucleation layer, a mean roughness of the outer layers (average ˜150 nm), which is comparable to that layer produced purely by high-frequency magnetron sputtering (sample No. 1). The outer layers of samples No. 7 and 8, which were subjected to vacuum breakage, showed improved roughness compared to the pure DC layer (sample No. 6). However, the roughness is about 50 nm lower at about 100 nm, compared to the layers without vacuum breakage. In the AFM images, as in the SEM images, the lateral dimensions of the individual craters are discernible. It was possible here to observe comparable lateral structural parameters to those as achievable in the case of pure HF layers. In addition, the layer which has been applied under the same conditions without a nucleation layer (parallel coating) exhibited a very much smaller lateral structure parameter.

An additional means of characterization of the samples is that of angle-resolved scattered light measurement, which gives the proportion of light scattered at different angle ranges. A morphology optimized for the application should scatter a maximum proportion of red and near infrared light at a large angle.

The light scattering of the etched ZnO:Al layers was studied experimentally on nucleation layers of different thickness (25 nm, 80 nm, 155 nm and 390 nm) at a wavelength of 700 nm. The samples were illuminated with perpendicular incidence from the layer side, while the detector collected the transmitted light at the different angles. The studies showed that all samples scatter the light essentially very efficiently. Both the shape and the intensity are similar to those values which can be obtained in the case of pure high-frequency magnetron sputtering deposition.

1-11. (canceled)

12: A process for coating a substrate with an aluminum-doped zinc oxide, which comprises the steps of:
producing a nucleation layer having a thickness between 5 nm and 400 nm and containing zinc oxide or doped, zinc oxide on a surface of the substrate by atomizing a solid-state target;
producing an outer layer which grows onto the nucleation layer in a quasi-epitaxial manner and contains aluminum-doped zinc oxide; and
wet-chemically etching the outer layer.

13: The process according to claim 12, which further comprises producing the nucleation layer on the substrate with a thickness between 5 nm and 30 nm.

14: The process according to claim 12, which further comprises producing the nucleation layer by high-frequency magnetron sputtering of a ceramic solid-state target which contains at least one of ZnO, a content of Al₂O₃ or any other dopants, and retains or at least virtually retains a lattice structure.

15: The process according to claim 14, which further comprises producing the nucleation layer using the ceramic solid-state target containing the ZnO and the content of Al₂O₃ being greater than 0% by weight and less than 1% by weight, and is atomized by high-frequency magnetron atomization at a temperature T>300° C.

16: The process according to claim 14, which further comprises producing the nucleation layer using the ceramic solid-state target containing the ZnO and the content of Al₂O₃ being between 1 and 2% by weight and is atomized by high-frequency magnetron atomization at a temperature T≦300° C.

17: The process according to claim 12, wherein a deposition rate with which the nucleation layer is applied to the substrate is less than 20 nm m/min.

18: The process according to claim 12, which further comprises producing the nucleation layer using a ceramic solid-state target containing at least one of ZnO, a content of Al₂O₃ or any other dopants and is atomized by DC magnetron sputtering, a deposition rate with which the nucleation layer is applied to the substrate being less than 20 nm m/min.

19: The process according to claim 12, wherein the outer layer which grows onto the nucleation layer is obtained by atomizing a ceramic solid-state target containing ZnO and a content of Al₂O₃ by DC magnetron atomization or DC pulsed magnetron atomization.

20: The process according to claim 12, which further comprises producing the outer layer which grows onto the nucleation layer by atomizing a metallic solid-state target containing aluminum-doped zinc oxide in a reactive gas process by DC magnetron atomization or moderate-frequency magnetron atomization.

21: The process according to claim 12, which further comprises producing the outer layer which grows onto the nucleation layer by performing at least one of the following steps:
performing a hollow cathode gas flow atomization process;
performing a vapor deposition process;
performing a wet-chemical deposition process;
performing an atmospheric chemical gas phase deposition (CVD) process;
performing a low-pressure CVD process;
performing an atmospheric plasma-enhanced chemical gas phase deposition (PECVD) process; or
performing a low-pressure PECVD process.

22: The process according to claim 12, which further comprises providing an aluminum-doped, zinc oxide as the doped, zinc oxide on the surface of the substrate.

23: A production method, which comprises the steps of
providing a substrate coated with an aluminum-doped zinc oxide created by the substrate being coated with a nucleation layer having a thickness between 5 nm and 400 nm and containing zinc oxide or doped, zinc oxide on a surface of the substrate by atomizing a solid-state target, an outer layer being grown onto the nucleation layer in a quasi-epitaxial manner and containing the aluminum-doped zinc oxide, and the outer layer being wet-chemically etched; and
forming the substrate into a front contact of a silicon thin-film solar cell.
